(19) United States
(12) Patent Application Publication
(10) Pub. No.: US 2006/0233950 A1
(43) Pub. Date: Oct. 19, 2006

(54) Method of fabricating organic electronic device

(75) Inventors: Jin Ha Kim, Sungnam (KR); Moo Youn Park, Koangmyung (KR); Hyun Kee Lee, Suwon (KR); Sung Min Cho, Yongin (KR)

Correspondence Address: VOLPE AND KOENIG, P.C., UNITED PLAZA, SUITE 1600, 30 SOUTH 17TH STREET, PHILADELPHIA, PA, 19103, US

(73) Assignee: Samsung Electro-Mechanics Co., Ltd., Suwon (KR)

(21) Appl. No.: 11/319,990

(22) Filed: Dec. 28, 2005

(30) Foreign Application Priority Data
Apr. 15, 2005 (KR) 10-2005-31605

(51) Int. Cl. B41M 3/12

(52) U.S. Cl. 427/148

(57) ABSTRACT

The invention relates to a method for fabricating an organic electronic device. The organic electronic device is fabricated by forming a first electrode layer, a plurality of organic layers and a second electrode layer sequentially on a substrate. In forming at least one of the organic layers, a donor film is coated with organic material to form an organic layer. The organic layer formed on the donor film is positioned on the first electrode layer or another one of the organic layers of the organic electronic device. Also, the organic layer is thermal-transferred to the first electrode layer or another organic layer. Finally, the donor film is removed from the organic layer.

### CLAIM OF PRIORITY

This application claims the benefit of Korean Patent Application No. 2005-31605 filed on Apr. 15, 2005, in the Korean Intellectual Property Office, the disclosure of which is incorporated herein by reference.

### BACKGROUND OF THE INVENTION

1. Field of the Invention

The present invention relates to a method for fabricating an organic electronic device, more particularly, a method for fabricating an organic electronic device capable of overcoming damage to a lower layer caused by solvent in an upper layer.

2. Description of the Related Art

In general, an organic electronic device has a plurality of organic layers formed between positive and negative electrodes, and includes an organic electroluminescent device, an organic thin film transistor, and an organic photovoltaic.

The organic electroluminescence device, a representative organic electronic device is made of a positive electrode, a negative electrode, a hole injection layer (HIL), a hole transport layer (HTL), an emitting layer (EML), an electron transport layer (ETL) and an electron injection layer (EIL).

More specifically, as shown in FIG. 1a, a general single-color organic light emitting device 10 has a positive electrode 12 such as ITO formed on a glass substrate 11. The positive electrode 12 may have an organic layer such as HIL/HTL, a single-color emitting layer 15, an organic layer 17 such as EIL/ETL and a negative electrode 18 sequentially formed thereon.

Recently, the organic electroluminescent device for emitting white light has a more complex organic emitting layer structure. FIG. 1b illustrates the organic electroluminescent device. A white light organic electroluminescent device 20, as shown in FIG. 1b, has a positive electrode 22 such as ITO, and an organic layer 23 such as HIT/HTL, an organic emitting layer 25 having blue, green, red light emitting layers 25a, 25b, 25c, an organic layer 27 such as EIL/ETL and a negative electrode 28 sequentially formed on the glass substrate 21.

Typically, the organic layer of the organic electronic device such as the organic electroluminescent device is broken down into low molecular weight and polymer layers according to material thereof. Low molecular weight material can be deposited repeatedly on a substrate via intrinsic thermal deposition, organic molecular beam deposition (OMBD) and organic vapor deposition. But, a polymer organic layer is formed by coating polymer organic material, which is dissolved into solution by solvent, via a wet process such as spin coating or ink jet printing, screen printing and doctor blading. Thereafter, the solvent is vaporized and then the organic layer is solidified.

In fabricating an organic layer via such a wet process, solvent for organic material to be coated may impair a previously formed lower organic layer, and thus suitable solvent should be selected.

But, as described above, since the organic electroluminescent device includes a plurality of organic layers, it is difficult to select adequate solvent to coat the organic layers therewith. Especially, this problem is aggravated in case of a greater number of organic layers required as shown in FIG. 1b.

For example, for an organic emitting layer shown in FIG. 1b, PPV (poly(1,4-phenylenevinylene)) derivative may be used to emit green and red light while PF (poly(fluorene)) derivative may be used to emit blue light. However, both PPV derivative and PF derivative are dissolved in organic solvent such as chlorobenzene, thus rendering it impossible to obtain a continuous organic layer.

Further, this problem is not limited to the organic emitting layer. In the case of low molecular weight LED (OLED), due to use of various layers such as electron injection layer, electron transport layer, and exciton blocking layer, selection of components of each organic layer is greatly restricted.

As noted above, a wet process for forming a polymeric organic material layer has rendered it difficult to achieve a continuous structure by the aforesaid solvent or select organic material of each organic layer.

### SUMMARY OF THE INVENTION

The present invention has been made to solve the foregoing problems of the prior art and it is therefore an object of the present invention to provide a novel method for fabricating an organic electronic device, in which an organic layer is formed on a donor film and then thermal-transferred to a necessary position to prevent damage to a lower organic layer caused by solvent.

According to an aspect of the invention for realizing the object, there is a method for fabricating an organic electronic device, by forming a first electrode layer, a plurality of organic layers and a second electrode layer sequentially on a substrate, wherein at least one of the organic layers is formed by following steps:
coating a donor film with organic material to form an organic layer;
positioning the organic layer formed on the donor film on the first electrode layer or another one of the organic layers of the organic electronic device;
thermal-transferring the organic layer to the first electrode layer or another organic layer; and
removing the donor film from the organic layer.

Preferably, the step of forming the organic layer on the donor film may be carried out by a process selected from a group consisting of spin coating, ink jet printing, screen printing and doctor blading.

Preferably, the organic layer thermal-transferring step may be carried out via a hot roller or a hot press. The organic layer thermal-transferring step comprises heating the organic layer at a temperature ranging from a glass transition temperature to a heat decomposition temperature of components of the organic layer.

In one embodiment of the invention, the organic layer comprises a hole injection layer formed on the substrate. The organic layer formed on the hole injection layer comprises at least 2 organic emitting layers made of different organic materials for emitting different wavelength light.

As described above, according to the invention, a wet coating process for forming an organic layer on a donor film and a dry printing method for thermal transferring an organic layer on a desired area are combined to effectively prevent damage to the lower organic layer caused by the solvent, and be applied more advantageously to a process for forming a large-sized organic light emitting device.

### BRIEF DESCRIPTION OF THE DRAWINGS

The above and other objects, features and other advantages of the present invention will be more clearly understood from the following detailed description taken in conjunction with the accompanying drawings, in which:

FIG. 1a and FIG. 1b are sectional views illustrating a conventional organic electroluminescence device;

FIG. 2 is a flow chart explaining a method for fabricating an organic electronic device according the invention; and

FIG. 3 is a schematic sectional view for explaining a process for forming an organic layer employed according to the invention.

### DETAILED DESCRIPTION OF THE PREFERRED EMBODIMENT

Preferred embodiments of the present invention will now be described in detail with reference to the accompanying drawings.

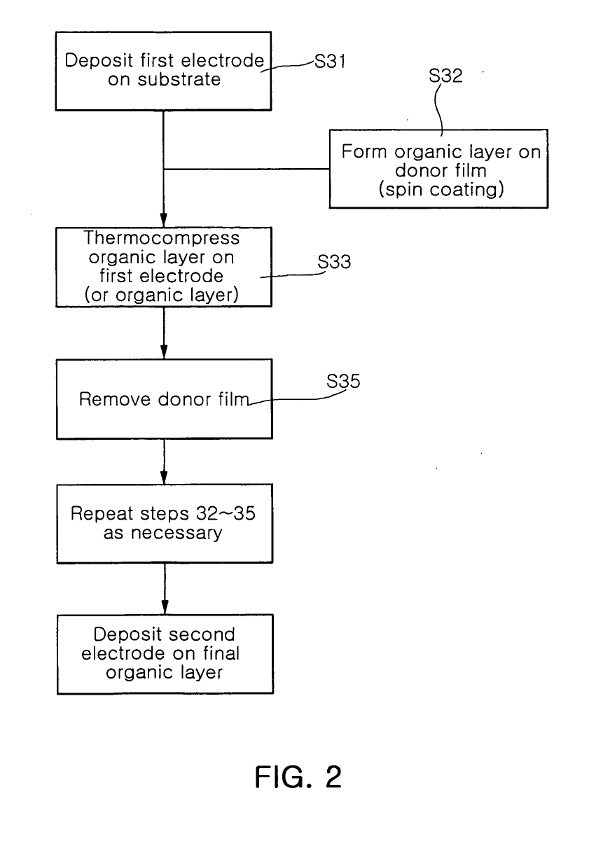

FIG. 2 is a flow chart explaining a method for fabricating an organic electronic device according to the invention.

To fabricate an organic electronic device according to the invention, first, a first electrode is deposited on a substrate in S31. In the case of an organic electroluminescent device, the substrate is a transparent substrate such as glass, PET, PEN, PES, and PI, and the first electrode may have a transparent positive electrode such as ITO. The first electrode material can be formed via a general deposition process.

Thereafter, a necessary organic layer is formed on the donor film via a typical wet coating process in S32. That is, materials to compose the organic layer are dissolved in solvent to be coated onto the donor film. Then, solvent is vaporized. The wet coating process may include spin coating, ink jet printing, screen printing and doctor blading.

The organic layer forming process may be carried out for a specific organic layer having damage in a lower layer caused by solvent, but also for an entire organic layer. That is, such a process may start with forming a first organic layer such as a hole injection layer. Alternatively, the hole injection layer, which is the first organic layer formed on the first electrode is less likely to be damaged in the lower layer by solvent. Therefore, the hole injection layer may be formed on the first electrode via a wet coating process.

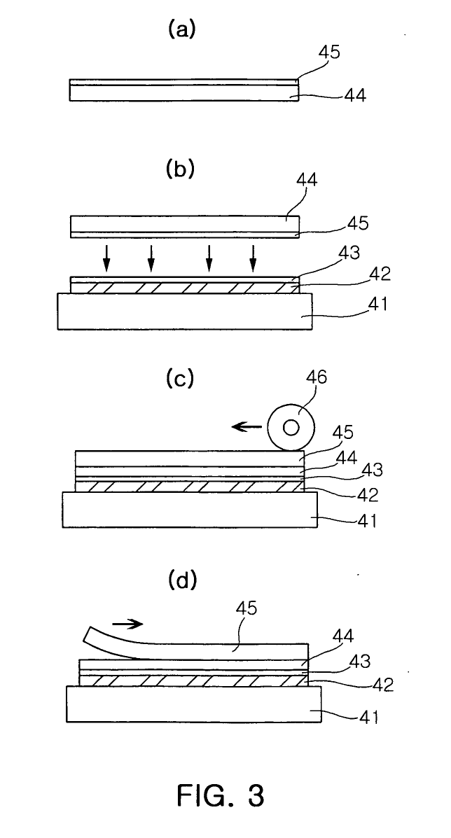

Then, the organic layer formed on a donor film is stacked on the first electrode or the previously formed lower organic layer and thermocompression is conducted in S33. In this process, the organic layer formed on the donor film is thermal-transferred to the first electrode or the lower organic layer formed. Thermocompression may be carried out easily via a hot roller or a hot press. But, thermocompression is performed under adequate conditions so that the organic layer formed on the donor film is sufficiently adhesive to the lower organic layer formed. The thermocompression conditions are explained in greater detail in FIG. 3d.

Thereafter, the donor film is removed from the organic layer in S35. Material for the donor film is properly selected to ensure that adhesion between the donor film and the organic layer is smaller than that of interface of the thermal-transferred organic layer. Alternatively, a separate release layer may be added between the donor film and the organic layer to allow easy separation.

The step S32 of forming an organic layer on the donor film and the step S33 of thermal-transferring the organic layer, and the step S35 of removing the donor film are repeatedly performed commensurate with the number of the organic layers required. According to the invention, the organic layer is formed via a wet coating process to easily form a polymeric organic layer. Also, the invention employs a dry printing process in which the organic layer formed on the donor film is thermal-transferred, thus preventing damage to the lower organic layer by solvent.

At last, a second electrode is deposited on the organic layer (e.g. electron injection layer) formed finally to form an organic electronic device. Mg:Ag, Ca/Al, and LiF/Al are mainly used as a material for the second electrode, which can be easily formed via a typical deposition process and an adequate doping process.

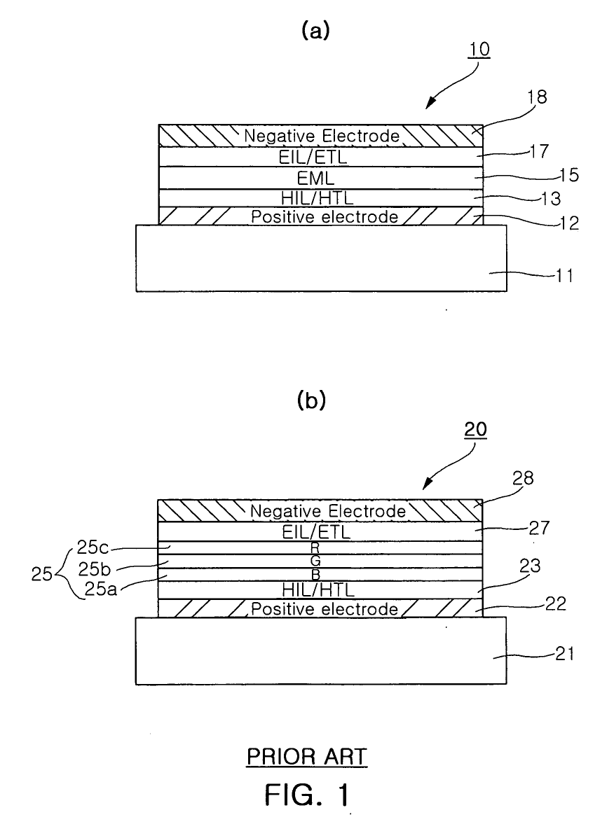

According to the method for fabricating the organic electronic device of the invention, a continuous organic emitting layer as shown in FIG. 1b can be formed easily without damage in the lower layer by solvent. That is, even if PPV derivative for emitting green and red light and PF derivative for emitting blue light are dissolved in chlorobenzene, respectively, the solution is coated onto a separate donor film, and then after solidification, thermal transfer is conducted to form the organic emitting layer on a positive electrode.

FIG. 3a and FIG. 3d are sectional views for explaining a process of forming an organic layer employed in the invention in greater detail. The organic layer forming process shows an example in which the first organic layer such as a hole injection layer is formed on ITO electrode via wet-coating.

As shown in FIG. 3a, a desired organic material is coated onto a donor film 44 and then solidified to form an organic layer 43. The donor film 44 may be a polymer film of, for example, polyester. The donor film 44 should be selected in such a way that adequate thermal stability and light transmissibility are ensured under thermal-transfer process conditions. For example, in the case where a thermal transfer process is conducted via laser beam, a material capable of transmitting laser beam should be selected. Also, in case where a hot roller is applied to the donor film as in this embodiment, preferably, sufficient thermal stability and heat conductivity should be ensured.

As shown in FIG. 3b, the resultant organic layer is positioned so that an organic layer 45 formed on the donor film 44 contacts the previously formed lower organic layer 43. The lower organic layer 43 may be a hole injection layer. As explained earlier, due to no restrictions placed on the lower organic layer materials, the hole injection layer 43 may be directly formed on a positive electrode of a substrate 41 via a wet process.

Next, as shown in FIG. 3c, a hot roller 46 is applied to the other side of a donor film 44 to be heated under a predetermined pressure so that the organic layer 44 is thermal-transferred to the lower organic layer 42. In this thermal-transfer process, an interface of the organic layer 43 adjoining the lower organic layer 42 should be heated at higher than or equal to a glass transfer temperature (T_{g}). However, preferably, the thermal transfer temperature should be lower than or equal to a heat decomposition temperature so that the organic layers 42, 43 are not impaired. Further, as in this embodiment, since the hot roller 46 enables thermal transfer, this can be applied more advantageously to a process of fabricating a large-sized organic electroluminescence device.

Then, as shown in FIG. 3d, the donor film 44 is removed from the thermal-transferred organic layer 43. The thermal transfer process conducted at a glass transfer temperature (T_{g}) or a higher temperature causes materials in the organic layer 43 to transit to the lower organic layer 42, leading to high adhesion. Therefore, in a process of FIG. 3a, adhesion between the donor film 44 and the organic layer 43 is sufficiently smaller than that between the thermal-transferred organic layers 42, 43 so that the donor film 44 can be easily removed.

As stated above, according to the invention, the lower organic layer is effectively prevented from suffering damage from solvent by combining a wet coating process of forming an organic layer on the donor film and a dry printing method of thermal-transferring the organic layer to a desired area. Also, according to the invention, in fabricating the organic electronic device, the hot roller or hot spray is used to perform thermal transfer. Therefore, this can be applied more advantageously to a process of forming a large-sized organic emitting layer.

While the present invention has been shown and described in connection with the preferred embodiments, it will be apparent to those skilled in the art that modifications and variations can be made without departing from the spirit and scope of the invention as defined by the appended claims.

What is claimed is:

1. A method for fabricating an organic electronic device, by forming a first electrode layer, a plurality of organic layers and a second electrode layer sequentially on a substrate, wherein at least one of the organic layers is formed by following steps:
coating a donor film with organic material to form an organic layer;
positioning the organic layer formed on the donor film on the first electrode layer or another one of the organic layers of the organic electronic device;
thermal-transferring the organic layer to the first electrode layer or another organic layer; and
removing the donor film from the organic layer.

2. The method according to claim 1, wherein the step of forming the organic layer on the donor film is carried out by a process selected from a group consisting of spin coating, ink jet printing, screen printing and doctor blading.

3. The method according to claim 1, wherein the organic layer thermal-transferring step is carried out via a hot roller or a hot press.

4. The method according to claim 1, wherein the organic layer thermal-transferring step comprises heating the organic layer at a temperature ranging from a glass transition temperature to a heat decomposition temperature of components of the organic layer.

5. The method according to claim 1, wherein the organic layer comprises a hole injection layer formed on the substrate.

6. The method according to claim 5, wherein the organic layer formed on the hole injection layer comprises at least 2 organic emitting layers made of different organic materials for emitting different wavelength light.
